(19) United States
(12) Patent Application Publication
(10) Pub. No.: US 2008/0297151 A1
(43) Pub. Date: Dec. 4, 2008

(54) MRI phantom and MRI system

(76) Inventors: Koji Hirata, Kasukabe (JP); Yosuke Otake, Hachioji (JP); Yoshihisa Soutome, Tokyo (JP); Yoshitaka Bito, Kokubunji (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/068,994

(22) Filed: Feb. 14, 2008

(30) Foreign Application Priority Data
Jun. 1, 2007 (JP) 2007-147391

(51) Int. Cl. G01R 33/48; G01R 33/58

(52) U.S. Cl. 324/307

(57) ABSTRACT

It is intended to provide a Magnetic Resonance Imaging (MRI) phantom for ¹H/¹⁹F signal detection that permits the stable and uniform dispersion of a vesicle and to accomplish the adjustment of a measurement parameter for a ¹H/¹⁹F signal and performance confirmation by use of the phantom. The present invention provides an MRI phantom having a gel comprising a vesicle comprising at least one of a perfluorocarbon and a superparamagnetic iron oxide particle and an MRI system having the phantom.

### CLAIM OF PRIORITY

The present application claims priority from Japanese application JP 2007-147391 filed on Jun. 1, 2007, the content of which is hereby incorporated by reference into this application.

### BACKGROUND OF THE INVENTION

1. Field of the Invention

The present invention relates to a Magnetic Resonance Imaging (MRI) phantom for ¹H/¹⁹F signal detection, an MRI system, and a method for adjusting a measurement parameter for a ¹H/¹⁹F signal by use of the MRI system.

2. Background Art

A Magnetic Resonance Imaging (MRI) apparatus induces a magnetic resonance phenomenon in a measurement target placed in a static magnetic field by irradiation with a high-frequency magnetic field at a particular frequency and acquires the physicochemical information of the measurement target. The MRI apparatus, which mainly utilizes the magnetic resonance phenomenon of the hydrogen nucleus in a water molecule, can image a difference in the density distribution or relaxation time of the hydrogen nucleus that differs among biological tissues. This can image a difference in tissue characterization and produces high effects in disease diagnosis. Widely diffused MRI apparatuses having a static magnetic field strength of 1.5 tesla or lower mainly image a concentration distribution that reflects the density distribution or relaxation time of the hydrogen nucleus in a water molecule. By contrast, MRI apparatuses having a higher static magnetic field strength, particularly, a static magnetic field strength of 3 tesla or higher, isolate a magnetic resonance signal on the basis of a chemical shift in which magnetic resonance frequencies of the atomic nuclei of multinuclear species such as ¹³C, ¹⁹F, and ³¹P differ depending on a difference in the chemical bond of the molecule. These MRI apparatuses can measure the concentration or relaxation time of each molecular species and accomplishes multinuclear MRI based on this technique.

¹⁹F is absent in living bodies by nature. All the ¹⁹F components in living bodies are foreign substances. Among multinuclear MRI techniques, particularly ¹H/¹⁹F-MRI can therefore offer the noninvasive detection of foreign chemicals such as pharmaceuticals in living bodies. There exist many anticancer agents containing ¹⁹F in their chemical structures, such as fluorouracil-based compounds. Therefore, ¹H/¹⁹F-MRI accomplishes the conventional diagnostic imaging of cancer principally aimed at morphologically understanding solid cancer tissues and also accomplishes a novel monitoring of anticancer agent distribution. Thus, ¹H/¹⁹F-MRI apparatuses are of great clinical significance.

The ¹H/¹⁹F-MRI apparatus particularly demonstrates its performance in diagnostic imaging examination using a contrast agent, that is, in contrast-enhanced MRI examination. For ¹H-MRI, plural MRI contrast agents mainly composed of a paramagnetic substance have already been placed on the market or are under research and development. For ¹⁹F-MRI, contrast agents specifically designed to contrast-enhanced ¹⁹F-MRI examination have not yet been placed on the market. However, an approach has been made in research to detect ¹⁹F components in living bodies by administering thereto the fluorouracil-based anticancer agents or a perfluorocarbon-containing compound (Proceedings of the International Society for Magnetic Resonance in Medicine, vol. 14, 1834, 2006, Proceedings of the International Society for Magnetic Resonance in Medicine, vol. 14, 3094, 2006, Proceedings of the International Society for Magnetic Resonance in Medicine, vol. 11, 2497, 2004, Magnetic Resonance in Medicine, vol. 46, 864, 2001, Investigative Radiology, vol. 20, 504, 1985).

On the other hand, for maintaining the good condition of an MRI apparatus in clinical practice, it is essential to perform the confirmation of operation of signal reception or signal processing performance, such as regular checks of an S/N ratio using a phantom. In general, an aqueous nickel chloride or nickel sulfate solution is often used as a substance contained in the phantom.

For practicing only non-contrast-enhanced MRI, the confirmation of MRI apparatus operation may be carried out by use of a phantom containing an aqueous nickel chloride, nickel sulfate, or copper sulfate solution. However, for also practicing contrast-enhanced ¹H-MRI or contrast-enhanced ¹⁹F-MRI, the confirmation of original operation is difficult to achieve unless phantoms containing their contrast agents are used. Under present circumstances, a perfluorocarbon or a superparamagnetic iron oxide particle used as a contrast agent in contrast-enhanced ¹H-MRI or contrast-enhanced ¹⁹F-MRI is hydrophobic and is of larger specific gravity in its aqueous solution form than that of an aqueous solution free of these compounds. Therefore, these compounds are precipitated in the bottom of the phantom container.

Specifically, the preparation of an MRI phantom comprising a perfluorocarbon or a superparamagnetic iron oxide particle requires subjecting these hydrophobic substances to solubilization treatment. For convenient solubilization treatment, it is preferred to make the substances into a vesicle. However, a vesicle comprising a perfluorocarbon or a superparamagnetic iron oxide particle cannot be dispersed uniformly over a long period in an aqueous solution due to its high specific gravity and was difficult to use in an MRI phantom. Therefore, a phantom that contains a contrast agent and keeps stable uniformity was difficult to achieve.

This absence of such a phantom made it difficult to acquire a stable magnetic resonance signal and to stably adjust a measurement parameter in an MRI system.

An object of the present invention is to achieve an MRI phantom containing, in a stably and uniformly dispersed state over a long period, a vesicle comprising a perfluorocarbon or a superparamagnetic iron oxide particle. A further object of the present invention is to achieve an MRI system capable of stably adjusting a measurement parameter by use of such an MRI phantom.

### SUMMARY OF THE INVENTION

In the present invention, to attain the object, a solution of a polymer compound capable of chemically forming a so-called network structure is mixed with a vesicle comprising any one of a perfluorocarbon and a superparamagnetic iron oxide particle. The mixture is gelated for fixation. This permits the vesicle to be maintained in a stably and uniformly dispersed state over a long period and can achieve an MRI phantom for ¹H/¹⁹F signal detection. The use of the phantom can achieve an MRI system capable of calculating an S/N ratio as performance confirmation means in a ¹H/¹⁹F-MRI apparatus.

Specifically, the present invention relates to an MRI phantom having a gel comprising a vesicle comprising at least one of a perfluorocarbon and a superparamagnetic iron oxide particle.

In the MRI phantom of the present invention, the perfluorocarbon that can be used is any of perfluoro-n-pentane, perfluoro-n-hexane, perfluoro-n-heptane, perfluoro-n-octane, perfluorotributylamine, and perfluoro-15-crown-5-ether. In this context, it is preferred to use any of perfluoro-n-hexane, perfluoro-n-heptane, perfluoro-n-octane, perfluorotributylamine, and perfluoro-15-crown-5-ether with a boiling point of 50° C. or higher, more preferably, any of perfluoro-n-octane, perfluorotributylamine, and perfluoro-15-crown-5-ether with a boiling point of 100° C. or higher, because the gelation process of acrylamide generates very slight heat.

Moreover, the superparamagnetic iron oxide particle that can be used is ferric oxide or ammonium iron citrate.

In the MRI phantom of the present invention, it is preferred that the shell of the vesicle should be composed mainly of lipid. Examples of the lipid include L-alpha-phosphatidyl choline, cholesterol, L-alpha-dilauroylphosphatidylcholine, L-alpha-dilauroylphosphatidylethanolamine, L-alpha-dilauroylphosphatidylglycerol sodium, L-alpha-monomyristoylphosphatidylcholine, L-alpha-dimyristoylphosphatidylcholine, L-alpha-dimyristoylphosphatidylethanolamine, L-alpha-dimyristoylphosphatidylglycerol ammonium, L-alpha-dimyristoylphosphatidylglycerol sodium, sodium L-alpha-dimyristoylphosphatidate, L-alpha-dioleylphosphatidylcholine, L-alpha-dioleoylphosphatidylethanolamine, L-alpha-dioleoylphosphatidylserine sodium, L-alpha-monopalmitoylphosphatidylcholine, L-alpha-dipalmitoylphosphatidylcholine, L-alpha-dipalmitoylphosphatidylethanolamine, L-alpha-dipalmitoylphosphatidylglycerol ammonium, L-alpha-dipalmitoylphosphatidylglycerol sodium, sodium L-alpha-dipalmitoylphosphatidate, L-alpha-stearoylphosphatidylcholine, L-alpha-distearoylphosphatidylcholine, L-alpha-distearoylphosphatidylethanolamine, L-alpha-distearoylphosphatidylglycerol sodium, L-alpha-distearoylphosphatidylglycerol ammonium, sodium L-alpha-distearoylphosphatidate, L-alpha-dierucoylphosphatidylcholine, 1-palmitoyl-2-oleoylphosphatidylcholine, beta-oleyl-gamma-palmitoyl-L-alpha-phosphatidylethanolamine, beta-oleyl-gamma-palmitoyl-L-alpha-phosphatidylglycerol sodium, sphingomyelin, and stearylamine. These lipids can be used alone or in combination of two or more of them.

In the MRI phantom of the present invention, the gel that can be used is composed of a polymer compound that chemically forms a network structure and is a substance comprising a mixed solution containing polyvinyl alcohol, agarose, or gelatin, preferably, acrylamide, bisacrylamide, ammonium persulfate, or N,N,N′,N′-tetramethylethylenediamine. It is particularly preferred that the gel should be composed of an acrylamide gel.

Examples of an embodiment of the present invention can include an MRI phantom having an acrylamide gel comprising a vesicle comprising perfluoro-n-octane and phosphatidylcholine.

Alternative examples of an embodiment of the present invention can include an MRI phantom having an acrylamide gel comprising a vesicle comprising ferric oxide and phosphatidylcholine.

The phantom of the present invention is useful in an MRI apparatus for ¹H/¹⁹F signal detection that performs irradiation with a magnetic field at a static magnetic field strength of 1.5 tesla or higher, particularly in an MRI apparatus ¹H/¹⁹F signal detection that performs irradiation with a magnetic field at a static magnetic field strength of 3.0 tesla or higher.

The present invention also provides an MRI system having: the MRI phantom of the present invention; a magnetic field irradiation part for applying a magnetic field to the phantom; a signal reception part for acquiring a magnetic signal from the phantom; a memory part for storing information about the magnetic signal; and a signal processing part for reading out the information from the memory part and performing predetermined signal processing.

Moreover, the present invention provides a method for adjusting a measurement parameter for a ¹H/¹⁹F signal by use of the MRI phantom of the present invention. Examples of the measurement parameter to be adjusted can include the strength of applied RF, an echo time, a repetition time, an echo train length, FOV, a matrix size, the number of excitations, a bandwidth, and a slice thickness.

The present invention provides an optimal Magnetic Resonance Imaging (MRI) phantom for ¹H/¹⁹F signal detection. The present invention can also achieve maintenance means for ¹H/¹⁹F signal reception performance and processing performance by use of the phantom and can provide an MRI system.

### BRIEF DESCRIPTION OF THE DRAWINGS

The patent or application file contains at least one drawing executed in color. Copies of this patent or patent application publication with color drawings will be provided by the Office upon request and payment of the necessary fee.

FIG. 1 shows an example of an MRI phantom for ¹H/¹⁹F signal detection;

FIG. 2 shows a schematic diagram of an example of an MRI system according to the present invention;

FIG. 3 shows a schematic diagram of a pulse sequence of Example 1;

FIG. 4 a ¹H/¹⁹F-MRI image of the sagittal plane of the phantom according to the present invention;

FIG. 5 shows a ¹⁹F-MRI image of the cross section of the phantom according to the present invention;

FIG. 6 shows a graph plotting values of S/N ratios shown in FIG. 5, which are standardized to a slice thickness of 4 mm and an imaging time of 6400 seconds; and

FIG. 7 shows an example of an MRI phantom for ¹H/¹⁹F signal detection.

### DETAILED DESCRIPTION OF THE PREFERRED EMBODIMENTS

Hereinafter, the present invention will be described specifically with reference to Examples. However, the present invention is not intended to be limited to these Examples.

### EXAMPLE 1

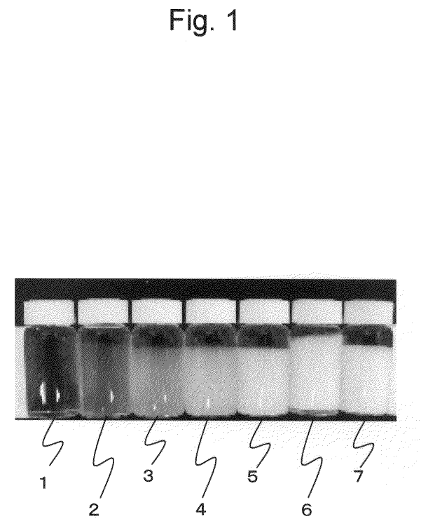

In this Example, a Magnetic Resonance Imaging (MRI) phantom for ¹H/¹⁹F signal detection will be described which permits the uniform dispersion of a vesicle comprising a perfluorocarbon by encapsulating the vesicle into a gel obtained from a polymer that chemically forms a network structure. FIG. 1 shows an example of the MRI phantom for ¹H/¹⁹F signal detection.

First, a method for producing a vesicle comprising perfluoro-n-octane as perfluorocarbon will be described. 6.667 mL of L-alpha-phosphatidylcholine (20 mg/mL) dissolved in chloroform and 1.757 mL of cholesterol (20 mg/mL) dissolved in chloroform were mixed, and this mixed solution was dried under reduced pressure at a reaction temperature of 30° C. for 10 minutes. To the dried product, 15 mL of a phosphate buffer solution was added, and the mixture was homogenized for 10 minutes under ice cooling with an ultrasonic homogenizer. To the obtained homogenate, 3.0 mL of perfluoro-n-octane was added. The mixture was emulsified at normal pressure for 10 seconds under ice cooling with a homogenizer and subsequently emulsified under high pressure conditions of 25 kPSI for 3 minutes under ice cooling with a high-pressure homogenizer to obtain a vesicle comprising 20% perfluoro-n-octane.

Subsequently, a method for producing a phantom having the vesicle comprising perfluoro-n-octane will be described. 7.35 mL of the vesicle comprising 20% perfluoro-n-octane, 7.35 mL in total of a mixed solution containing 3.675 mL of a phosphate buffer solution added to 3.675 mL of the vesicle comprising 20% perfluoro-n-octane, 7.35 mL in total of a mixed solution containing 6.615 mL of a phosphate buffer solution added to 0.735 mL of the vesicle comprising 20% perfluoro-n-octane, 7.35 mL in total of a mixed solution containing 6.9825 mL of a phosphate buffer solution added to 0.3675 mL of the vesicle comprising 20% perfluoro-n-octane, 7.35 mL in total of a mixed solution containing 7.2765 mL of a phosphate buffer solution added to 0.0735 mL of the vesicle comprising 20% perfluoro-n-octane, and 7.35 mL in total of a mixed solution containing 7.31325 mL of a phosphate buffer solution added to 0.03675 mL of the vesicle comprising 20% perfluoro-n-octane were separately prepared. 7.35 mL of the vesicle with any of these concentrations was mixed with 3.75 mL of a 40% acrylamide solution containing 38.5% acrylamide and 1.5% bisacrylamide and with 3.75 mL of purified water, and the mixtures were stirred. Each of these solutions was subsequently mixed with 0.15 mL of a 10% ammonium persulfate solution and 0.015 mL of N,N,N′,N′-tetramethylethylenediamine, and the mixtures were then quickly stirred. The mixed solutions were transferred to 20-mL glass vials and left standing for 30 minutes. In this way, an acrylamide gel comprising the vesicle comprising perfluoro-n-octane at a final concentration of 10%, 5%, 1%, 0.5%, 0.1%, or 0.05% was prepared in the 20-mL glass vial. To prevent air from entering the gel in each vial, a layer of purified water for hermetically sealing the vial was further stacked on the gel in the vial to produce phantoms shown in FIG. 1 (1, 2, 3, 4, 5, 6, and 7 of FIG. 1). In this context, the concentrations and amounts of the compounds described here are provided for illustrative purposes and are not intended to be limited to these descriptions.

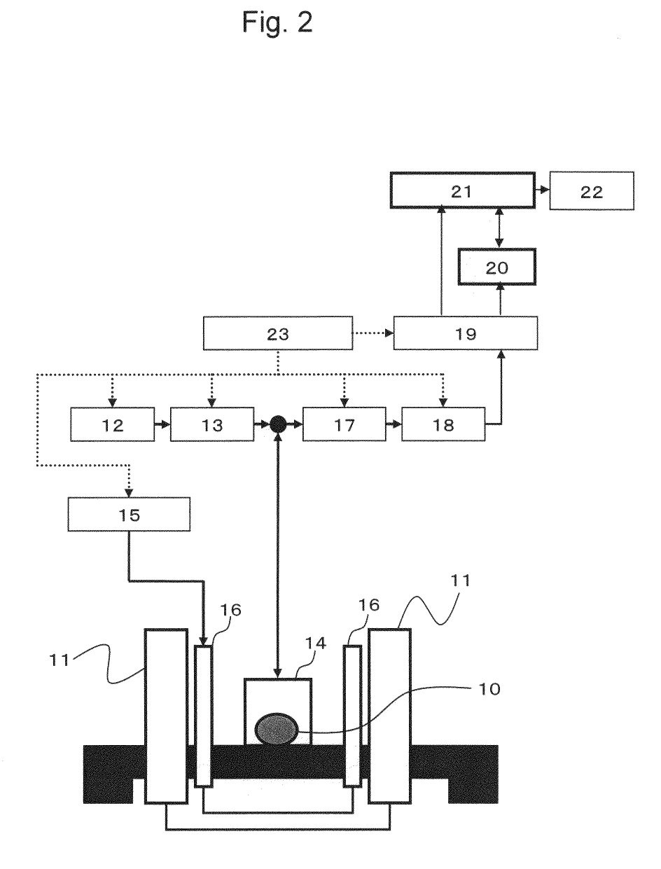

Next, a schematic diagram of an example of an MRI system according to the present invention is shown in FIG. 2. In FIG. 2, reference numeral 10 denotes a phantom having: a vesicle comprising at least one of perfluorocarbon and a superparamagnetic iron oxide particle; and a gel. Reference numeral 11 denotes a static magnetic field-generating magnet as a magnetic field irradiation part. Reference numeral 12 denotes a synthesizer for generating a high frequency. Reference numeral 13 denotes a modulator for waveform-shaping and power-amplifying the high frequency generated in the synthesizer 12. Reference numeral 14 denotes a high-frequency magnetic field coil as a signal reception part. Reference numeral 15 denotes a gradient magnetic field power supply for supplying power to a gradient magnetic field coil 16. Reference numeral 16 denotes a gradient magnetic field-generating coil as a magnetic field irradiation part for generating a gradient magnetic field. Reference numeral 17 denotes an amplifier for amplifying a magnetic resonance signal detected in the high-frequency magnetic field coil 14. Reference numeral 18 denotes an AD converter for AD-converting the magnetic resonance signal sent from the amplifier 17. Reference numeral 19 denotes a data processing apparatus for performing an operation on data. Reference numeral 20 denotes a memory part for storing information about the magnetic resonance signal processed in the data processing apparatus 19. Reference numeral 21 denotes a signal processing part for reading out the magnetic resonance information from the memory part 20 and comparing it with the magnetic resonance information acquired in the signal reception part 14 and sent from the data processing apparatus 19. Reference numeral 22 denotes a display for displaying the processing result of the signal processing part 21. Reference numeral 23 denotes a controller for controlling the generation timing and strength of each magnetic field. In this context, a fixing tool may be used to fix the phantom 10 at a correct position.

Next, the operation of this apparatus will be summarized. A high-frequency magnetic field pulse that excites the nuclear spin of the phantom 10 is generated by waveform-shaping and power-amplifying, in the modulator 13, a high frequency generated from the synthesizer 12 and supplying an electric current to the high-frequency magnetic field coil 14. The gradient magnetic field-generating coil 16, which has received an electric current supplied from the gradient magnetic field power supply 15, generates a gradient magnetic field and modulates a magnetic resonance signal from the phantom 10. The modulated signal is received by the high-frequency magnetic field coil 14 and amplified in the amplifier 17. The amplified signal is AD-converted in the AD converter 18 and then input into the data processing apparatus 19. The data processing apparatus 19 performs an operation and then sends the operation result to the memory part 20 and the signal processing part 21. The memory part 20 stores information about the magnetic resonance signal sent from the data processing apparatus 19. The signal processing part 21 reads out the information about the magnetic resonance signal from the memory part 20 and compares it with the magnetic resonance signal acquired in the signal reception part 14 and sent from the data processing apparatus 19. The display 22 displays the processing result of the signal processing part 21. The controller 23 provides a control so that each apparatus operates in the preprogrammed timing and at the preprogrammed strength.

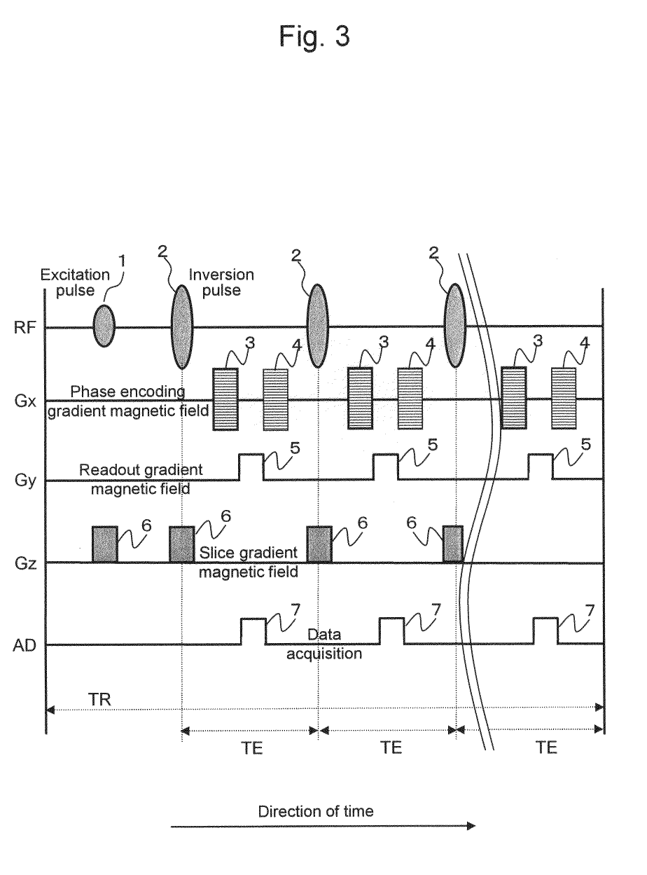

FIG. 3 shows a schematic diagram of a pulse sequence according to the present invention. A slice gradient magnetic field pulse 6 in the z direction as well as an excitation high-frequency magnetic field pulse 1 is applied to induce a nuclear magnetic resonance phenomenon in the given slice in the z direction. Next, the slice gradient magnetic field pulse 6 in the z direction as well as an inversion high-frequency magnetic field pulse 2 is applied to invert magnetization in the given slice in the z direction. An echo generated from the selected slice is modulated by the application of a phase encoding gradient magnetic field pulse 3 in the x direction and then data-acquired 7 during the application of a readout gradient magnetic field pulse 5 in the y direction. Prior to the subsequent application of the inversion high-frequency magnetic field pulse 2 and the slice gradient magnetic field pulse 6, a rewind gradient magnetic field pulse 4 is applied to restore the phase encoding to which the phase encoding gradient magnetic field pulse 3 has been applied. In the pulse sequence for imaging, for example, an echo planar imaging method (Journal of Physics, vol. C10, L55-L58, 1977) may be used, in addition to the method described above. Alternatively, the sections of scanning may be changed by switching the x, y, and z directions; or the direction of application of the phase encoding gradient magnetic field pulse may be changed to the z direction to obtain three-dimensional spatial information. Needless to say, the method of the present invention is also applicable to the imaging of one-dimensional spatial information (profile).

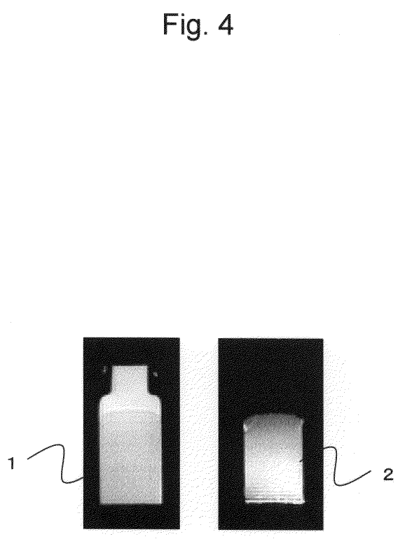

Subsequently, the MRI phantom for ¹H/¹⁹F signal detection of the present invention and ¹H/¹⁹F-MRI using this apparatus will be described. FIG. 4 shows ¹H/¹⁹F-MRI images of the sagittal planes of some of the phantoms shown in FIG. 1, which are obtained according to the operation of the MRI system shown in FIG. 2. In FIG. 4, reference numeral 1 denotes a ¹H-MRI image of the sagittal plane of the MRI phantom for ¹H/¹⁹F signal detection having an acrylamide gel comprising the vesicle comprising 10% perfluoro-n-octane. Reference numeral 2 denotes a ¹⁹F-MRI image of the sagittal plane of the MRI phantom for ¹H/¹⁹F signal detection having an acrylamide gel comprising the vesicle comprising 10% perfluoro-n-octane. FIG. 4 can demonstrate that in the image 1, ¹H components derived from the gel portion and ¹H components derived from a purified water layer stacked on the gel portion can be dispersed uniformly in the phantom container. FIG. 4 can also demonstrate that in the image 2, only ¹⁹F components described from the gel portion can be dispersed uniformly in the container. In this context, main imaging parameters for realizing the image 1 are, for example, sequence: Fast-spin echo method, TR/TE: 4000/25 msec., echo train length: 8, FOV: 100 mm×100 mm, matrix size: 128×128, the number of excitations: 8, bandwidth: 85 kHz, and slice thickness: 3 mm, provided that an MRI apparatus having a static magnetic field strength of 3 tesla is used. Main imaging parameters for realizing the image 2 are, for example, sequence: Fast-spin echo method, TR/TE: 4000/25 msec., echo train length: 8, FOV: 100 mm×100 mm, matrix size: 128×128, the number of excitations: 8, bandwidth: 12 kHz, and slice thickness: 3 mm, provided that an MRI apparatus having a static magnetic field strength of 3 tesla is used.

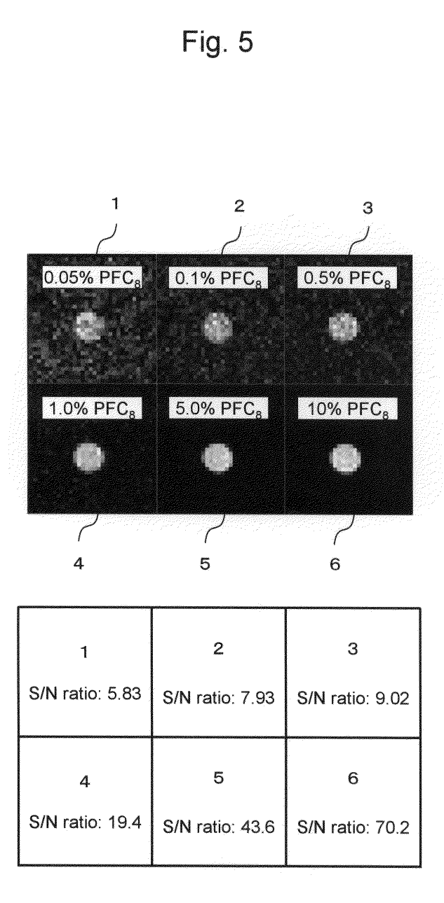

FIG. 5 shows ¹⁹F-MRI images of the cross sections of some of the phantoms shown in FIG. 1, which are obtained according to the operation of the MRI system shown in FIG. 2. In FIG. 5, reference numeral 1 denotes a ¹⁹F-MRI image of the cross section of the MRI phantom for ¹H/¹⁹F signal detection having an acrylamide gel comprising the vesicle comprising 0.05% perfluoro-n-octane. Reference numeral 2 denotes a ¹⁹F-MRI image of the cross section of the MRI phantom for ¹H/¹⁹F signal detection having an acrylamide gel comprising the vesicle comprising 0.1% perfluoro-n-octane. Reference numeral 3 denotes a ¹⁹F-MRI image of the cross section of the MRI phantom for ¹H/¹⁹F signal detection having an acrylamide gel comprising the vesicle comprising 0.5% perfluoro-n-octane. Reference numeral 4 denotes a ¹⁹F-MRI image of the cross section of the MRI phantom for ¹H/¹⁹F signal detection having an acrylamide gel comprising the vesicle comprising 1.0% perfluoro-n-octane. Reference numeral 5 denotes a ¹⁹F-MRI image of the cross section of the MRI phantom for ¹H/¹⁹F signal detection having an acrylamide gel comprising the vesicle comprising 5.0% perfluoro-n-octane. Reference numeral 6 denotes a ¹⁹F-MRI image of the cross section of the MRI phantom for ¹H/¹⁹F signal detection having an acrylamide gel comprising the vesicle comprising 10% perfluoro-n-octane. Main imaging parameters for realizing the image 1 are, for example, sequence: Fast-spin echo method, TR/TE: 4000/24 msec., echo spacing: 12 msec., echo train length: 32, FOV: 100 mm×100 mm, matrix size: 32×32, the number of excitations: 1600, bandwidth: 6 kHz, and slice thickness: 4 mm, provided that an MRI apparatus having a static magnetic field strength of 3 tesla is used. Main imaging parameters for realizing the image 2 are, for example, sequence: Fast-spin echo method, TR/TE: 4000/24 msec., echo spacing: 12 msec., echo train length: 32, FOV: 100 mm×100 mm, matrix size: 32×32, the number of excitations: 64, bandwidth: 6 kHz, and slice thickness: 4 mm, provided that an MRI apparatus having a static magnetic field strength of 3 tesla is used. Main imaging parameters for realizing the image 3 are, for example, sequence: Fast-spin echo method, TR/TE: 4000/24 msec., echo spacing: 12 msec., echo train length: 32, FOV: 100 mm×100 mm, matrix size: 32×32, the number of excitations: 16, bandwidth: 6 kHz, and slice thickness: 4 mm, provided that an MRI apparatus having a static magnetic field strength of 3 tesla is used. Main imaging parameters for realizing the image 4 are, for example, sequence: Fast-spin echo method, TR/TE: 4000/24 msec., echo spacing: 12 msec., echo train length: 32, FOV: 100 mm×100 mm, matrix size: 32×32, the number of excitations: 4, bandwidth: 6 kHz, and slice thickness: 4 mm, provided that an MRI apparatus having a static magnetic field strength of 3 tesla is used. Main imaging parameters for realizing the image 5 are, for example, sequence: Fast-spin echo method, TR/TE: 4000/24 msec., echo spacing: 12 msec., echo train length: 32, FOV: 100 mm×100 mm, matrix size: 32×32, the number of excitations: 4, bandwidth: 6 kHz, and slice thickness: 4 mm, provided that an MRI apparatus having a static magnetic field strength of 3 tesla is used. Main imaging parameters for realizing the image 6 are, for example, sequence: Fast-spin echo method, TR/TE: 4000/24 msec., echo spacing: 12 msec., echo train length: 32, FOV: 100 mm×100 mm, matrix size: 32×32, the number of excitations: 1, bandwidth: 6 kHz, and slice thickness: 2 provided that an MRI apparatus having a static magnetic field strength of 3 tesla is used.

In this context, for stably acquiring a ¹⁹F signal, it is desired that ¹⁹F should be dispersed uniformly in the phantom. The absence of uniform dispersion changes signal strength with a time change, depending on a slice position. Moreover, a change in concentration changes T2 or T1 and gives different image contrasts at values conventionally used for adjusting measurement parameters, resulting in a need of readjustment in some cases. The measurement parameters described here are, for example, the strength of applied RF, an echo time TE, a repetition time TR, and the value of a trimmer condenser for RF coil tuning. These changes in signal strength and in adjustment value can be prevented by uniformly dispersing 1⁹F in the phantom.

S/N ratios calculated from these ¹⁹F-MRI images were determined to be 5.83 for the image 1, 7.93 for the image 2, 9.02 for the image 3, 19.4 for the image 4, 43.6 for the image 5, and 70.2 for the image 6 according to the operation of the MRI system shown in FIG. 2. In this context, the S/N ratios were obtained by use of a one-region-of-interest method wherein the average signal value of each pixel in a region of interest in a phantom image is divided by the standard deviation of each pixel in this region of interest. In this approach, the MRI system shown in FIG. 2 performs a series of operations in such a way that the memory part 20 stores information about the magnetic resonance signal sent from the data processing apparatus 19; and the signal processing part 21 reads out the information about the magnetic resonance signal from the memory part 20 and compares it with the magnetic resonance signal acquired in the signal reception part 14 and sent from the data processing apparatus 19. S/N ratios obtained as a result of the same operations performed in the past are stored in the memory part 20 and can be compared with day-to-day S/N ratios in the signal processing part 21. Specifically, the present invention therefore achieves maintenance means for the day-to-day ¹⁹F signal reception performance or signal processing performance of a ¹⁹F-MRI apparatus.

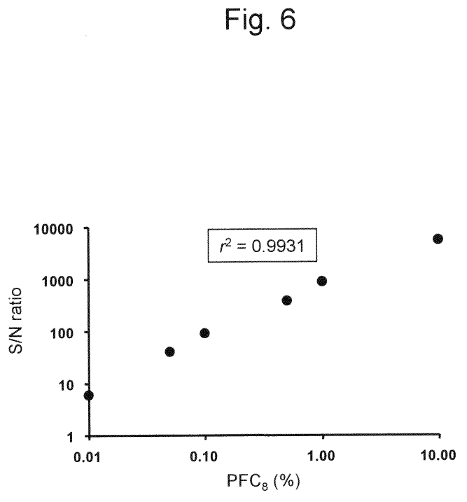

FIG. 6 shows a graph plotting values of the S/N ratios calculated from the ¹⁹F-MRI images of the cross sections of some of the phantoms shown in FIG. 5, which are standardized to a slice thickness of 4 mm and an imaging time of 6400 seconds, wherein the values are plotted in a double logarithmic graph with the logarithm of the concentration of the vesicle comprising perfluoro-n-octane as abscissa against the logarithm of the S/N ratio as ordinate. A correlation coefficient r² of each plot value calculated here was 0.9931. The results shown in FIG. 6 can demonstrate that the MRI phantom of the present invention is optimal for maintenance means for the ¹⁹F signal reception performance or signal processing performance of a ¹⁹F-MRI apparatus.

### EXAMPLE 2

In this Example, a Magnetic Resonance Imaging (MRI) phantom for ¹H/¹⁹F signal detection will be described which permits the uniform dispersion of a vesicle comprising a superparamagnetic iron oxide particle by encapsulating the vesicle into a gel obtained from a polymer that chemically forms a network structure.

First, a method for producing a vesicle comprising ferric oxide as a superparamagnetic iron oxide particle will be described. 6.667 mL of L-alpha-phosphatidylcholine (20 mg/mL) dissolved in chloroform and 1.757 mL of cholesterol (20 mg/mL) dissolved in chloroform were mixed, and this mixed solution was dried under reduced pressure at a reaction temperature of 30° C. for 10 minutes. To the dried product, 15 mL of a phosphate buffer solution was added, and the mixture was homogenized for 10 minutes under ice cooling with an ultrasonic homogenizer. To the obtained homogenate, 3.0 mL of 0.025% ferric oxide was added. The mixture was emulsified at normal pressure for 10 seconds under ice cooling with a homogenizer and subsequently emulsified under high pressure conditions of 25 kPSI for 3 minutes under ice cooling with a high-pressure homogenizer to obtain a vesicle comprising 0.005% ferric oxide.

Subsequently, a method for producing a phantom having the vesicle comprising ferric oxide will be described. 7.35 mL of the vesicle comprising 0.005% ferric oxide was prepared. 7.35 mL of this vesicle was mixed with 3.75 mL of a 40% acrylamide solution containing 38.5% acrylamide and 1.5% bisacrylamide and with 3.75 mL of purified water, and the mixture was stirred. This solution were subsequently mixed with 0.15 mL of a 10% ammonium persulfate solution and 0.015 mL of N,N,N′,N′-tetramethylethylenediamine, and the mixture was then quickly stirred. The mixed solution was transferred to a 20-mL glass vial and left standing for 30 minutes. In this way, an acrylamide gel comprising the vesicle comprising ferric oxide at a final concentration of 0.0025% was produced in the 20-mL glass vial. To prevent air from entering the gel in the vial, a layer of purified water for hermetically sealing the vial was further stacked on the gel in the vial to produce a phantom. In this context, the concentrations and amounts of the compounds described here are provided for illustrative purposes and are not intended to be limited to these descriptions.

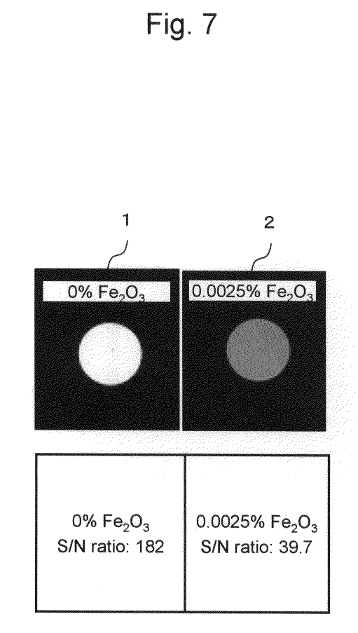

FIG. 7 shows a ¹H-MRI image of the cross section of the phantom, which is obtained according to the operation of the MRI system shown in FIG. 2. In FIG. 7, reference numeral 1 denotes a ¹H-MRI image of the cross section of an MRI phantom for ¹H/¹⁹F signal detection having an acrylamide gel comprising a vesicle free of ferric oxide. Reference numeral 2 denotes a ¹H-MRI image of the cross section of the MRI phantom for ¹H/¹⁹F signal detection having an acrylamide gel comprising the vesicle comprising 0.0025% ferric oxide. Main imaging parameters for realizing the image 1 are, for example, sequence: Gradient echo method, TR/TE: 50/10 msec., FOV: 100 mm×100 mm, matrix size: 128×128, the number of excitations: 1, bandwidth: 33.9 kHz, and slice thickness: 5 mm, provided that an MRI apparatus having a static magnetic field strength of 3 tesla is used. Main imaging parameters for realizing the image 2 are, for example, sequence: Gradient echo method, TR/TE: 50/10 msec., FOV: 100 mm×100 mm, matrix size: 128×128, the number of excitations: 1, bandwidth: 33.9 kHz, and slice thickness: 5 mm, provided that an MRI apparatus having a static magnetic field strength of 3 tesla is used. S/N ratios calculated from these ¹H-MRI images were determined to be 182 for the image 1 and 39.7 for the image 2 according to the operation of the MRI system shown in FIG. 2. In this context, the S/N ratios were obtained by use of a one-region-of-interest method wherein the average signal value of each pixel in a region of interest in a phantom image is divided by the standard deviation of each pixel in this region of interest. In this approach, the MRI system shown in FIG. 2 performs a series of operations in such a way that the memory part 20 stores information about the magnetic resonance signal sent from the data processing apparatus 19; and the signal processing part 21 reads out the information about the magnetic resonance signal from the memory part 20 and compares it with the magnetic resonance signal acquired in the signal reception part 14 and sent from the data processing apparatus 19. S/N ratios obtained as a result of the same operations performed in the past are stored in the memory part 20 and can be compared with day-to-day S/N ratios in the signal processing part 21. Specifically, the present invention therefore achieves maintenance means for the day-to-day ¹H-signal reception performance or signal processing performance of a ¹H-MRI apparatus.

The phantom of the present invention is useful in the adjustment of a measurement parameter and performance confirmation in an MRI system for ¹H/¹⁹F signal detection and is available in medical and medical equipment fields that require MRI diagnosis.

What is claimed is:

1. An MRI phantom having a gel comprising a vesicle comprising at least one of a perfluorocarbon and a superparamagnetic iron oxide particle.

2. The MRI phantom according to claim 1, wherein the perfluorocarbon is any selected from the group consisting of perfluoro-n-pentane, perfluoro-n-hexane, perfluoro-n-heptane, perfluoro-n-octane, perfluorotributylamine, and perfluoro-15-crown-5-ether.

3. The MRI phantom according to claim 1, wherein the superparamagnetic iron oxide particle is ferric oxide or ammonium iron citrate.

4. The MRI phantom according to claim 1, wherein the shell of the vesicle comprises lipid.

5. The MRI phantom according to claim 1, wherein the gel is an acrylamide gel.

6. The MRI phantom according to claim 1, wherein the MRI phantom has an acrylamide gel comprising a vesicle comprising perfluoro-n-octane and phosphatidylcholine.

7. The MRI phantom according to claim 1, wherein the MRI phantom has an acrylamide gel comprising a vesicle comprising ferric oxide and phosphatidylcholine.

8. The MRI phantom according to claim 1, wherein the MRI has a static magnetic field strength of 1.5 tesla or higher.

9. The MRI phantom according to claim 1, wherein the MRI has a static magnetic field strength of 3.0 tesla or higher.

10. An MRI system having:
an MRI phantom having a gel comprising a vesicle comprising at least one of a perfluorocarbon and a superparamagnetic iron oxide particle;
a magnetic field irradiation part for applying a magnetic field to the phantom;
a signal reception part for acquiring a magnetic signal from the phantom;
a memory part for storing information about the magnetic signal; and
a signal processing part for reading out the information from the memory part and performing predetermined signal processing.

11. The MRI system according to claim 10, wherein the perfluorocarbon is any selected from the group consisting of perfluoro-n-pentane, perfluoro-n-hexane, perfluoro-n-heptane, perfluoro-n-octane, perfluorotributylamine, and perfluoro-15-crown-5-ether.

12. The MRI system according to claim 10, wherein the superparamagnetic iron oxide particle is ferric oxide or ammonium iron citrate.

13. The MRI system according to claim 10, wherein the shell of the vesicle comprises lipid.

14. The MRI system according to claim 10, wherein the gel is an acrylamide gel.

15. The MRI system according to claim 10, wherein the MRI system has an acrylamide gel comprising a vesicle comprising perfluoro-n-octane and phosphatidylcholine.

16. The MRI system according to claim 10, wherein the MRI system has an acrylamide gel comprising a vesicle comprising ferric oxide and phosphatidylcholine.

17. The MRI system according to claim 10, wherein the magnetic field irradiation part performs irradiation with a magnetic field at a static magnetic field strength of 1.5 tesla or higher.

18. The MRI system according to claim 10, wherein the magnetic field irradiation part performs irradiation with a magnetic field at a static magnetic field strength of 3.0 tesla or higher.

19. A method for adjusting a measurement parameter for a ¹H/¹⁹F signal in an MRI apparatus by use of an MRI phantom according to claim 1.

20. The method according to claim 19, wherein the measurement parameter for a ¹H/¹⁹F signal is one or more selected from the strength of applied RF, an echo time, a repetition time, an echo train length, FOV, a matrix size, the number of excitations, a bandwidth, and a slice thickness.
